(19) United States
(12) Patent Application Publication
(10) Pub. No.: US 2024/0068738 A1
(43) Pub. Date: Feb. 29, 2024

(54) CONTROL BOX AND REFRIGERATOR INCLUDING A CONTROL BOX

(71) Applicant: SAMSUNG ELECTRONICS CO., LTD., Suwon-si (KR)

(72) Inventors: Wonho JANG, Suwon-si (KR); Inyong HWANG, Suwon-si (KR); Yongman SEO, Suwon-si (KR); Yountae SHIN, Suwon-si (KR)

(21) Appl. No.: 18/388,039

(22) Filed: Nov. 8, 2023

Related U.S. Application Data
(63) Continuation of application No. PCT/KR2022/008841, filed on Jun. 22, 2022.

(30) Foreign Application Priority Data
Jul. 15, 2021 (KR) 10-2021-0093088

(51) Int. Cl. F25D 23/06; F25D 29/00

(52) U.S. Cl. CPC F25D 23/065; F25D 29/005; F25D 2400/40

(57) ABSTRACT

A control box and a refrigerator comprising same are disclosed. The refrigerator may comprise: a main body; a storage compartment provided within the main body; a housing body which is disposed at the rear of the main body and is open at one side thereof to accommodate electrical/electronic components therein; and a housing cover which is coupled to the housing body to cover the open side of the housing body, wherein: the housing body includes a plurality of ribs which protrude toward the housing cover; and the housing cover includes contact portions which are formed in the housing cover to correspond to the ribs and are brought into contact with the ribs when an impact is applied to the housing cover.

### CROSS-REFERENCE TO RELATED APPLICATIONS

This application is a continuation application, claiming priority under § 365(c), of International Application No. PCT/KR2022/008841, filed on Jun. 22, 2022, which is based on and claims the benefit of Korean patent application number 10-2021-0093088 filed on Jul. 15, 2021, in the Korean Intellectual Property Office, the disclosures of which are incorporated by reference herein in their entireties.

### TECHNICAL FIELD

The disclosure relates to a refrigerator, and more specifically, to a refrigerator including a control box coupled to a rear side of the refrigerator.

### BACKGROUND ART

A refrigerator is an appliance which keeps food fresh. The refrigerator may include a main body provided with a storage compartment formed therein and a front that is open, a door installed to open and close the opening of the front of the main body, and a cold air supply device to supply the storage compartment with cold air.

Various electrical components are required to operate the cold air supply device of the refrigerator. For example, the electrical components can include a board, a condenser, a capacitor, and the like. Typically, such electrical components are stored in a control box. A control box may not only protect electrical components from external shocks, but also allow the electrical components to be accommodated in one place for easy management.

The control box can be attached to an outer side of the main body of the refrigerator. Since the control box is a part that is exposed to the outside, there is a risk of shock being applied to the control box during transportation of the refrigerator. When a shock is applied to the control box, the shock may be transmitted to the electrical components accommodated inside the control box, causing the electrical components to malfunction. Accordingly, there is a need for a structure that, even when a shock is applied to a control box, is able to prevent or minimize transmission of the shock to the electrical components.

### DISCLOSURE

### Technical Problem

One aspect of the disclosure provides a refrigerator including a rib and a contact protrusion that, even when a shock is applied to a control box, disperse the shock which may otherwise be applied to electrical components.

One aspect of the disclosure provides a refrigerator in which a rib and a contact protrusion of a control box are spaced apart from each other at a predetermined distance and thus prevent noise from occurring despite vibration of the refrigerator.

One aspect of the disclosure provides a refrigerator in which a housing cover is provided with a plurality of embossing portions and thus is deformed to a relatively small extent in response to a shock being applied thereto.

According to an aspect of the disclosure, there is provided a refrigerator including: a main body; a storage compartment arranged inside the main body; a housing body located at a rear of the main body and having a side that is open to accommodate an electrical component, the housing body including an inner surface facing an inside of the housing body and an outer surface opposite to the inner surface; and a housing cover coupled to the housing body to cover the open side of the housing body, wherein the housing body includes a plurality of ribs protruding toward the housing cover, and the housing cover includes a contact protrusion formed on an inner surface of the housing cover to correspond with the rib, the contact protrusion formed to protrude toward the rib and configured to, in response to a shock being applied to the housing cover, contact the rib.

The rib and the contact protrusion may be located adjacent to the electrical component.

The rib and the contact protrusion may be spaced apart from each other.

The housing cover may further include a recess formed on an outer surface thereof to correspond with the contact protrusion.

The contact protrusion may include a rounded shape at an end facing toward the housing body.

The contact protrusion may comprise a compliant pad element facing the rib.

The rib may be formed at a height such that the rib may be prevented from protruding beyond a rear surface of the refrigerator based on the housing body being coupled to the rear surface of the refrigerator.

The rib may comprise a compliant pad element and the rib and the compliant pad element are formed at a total height such that the rib and the compliant pad element are prevented from protruding beyond a rear surface of the refrigerator when the housing body is coupled to the rear surface.

The housing cover may include a metal material, and the contact protrusion may be deformable according to contact between the rib and the contact protrusion.

The housing cover may include at least one embossing portion formed by an outer surface of the housing cover protruding to form a recess on the inner surface of the housing cover.

The at least one embossing portion may include a first embossing portion formed at a position corresponding to the electrical component and a second embossing portion protruding from an outer surface of the first embossing portion.

The first and second embossing portions may form multiple steps.

The first and second embossing portions may form a single step.

The contact protrusion may be formed on an edge of the at least one embossing portion.

The contact protrusion may protrude in a direction opposite to a protruding direction of the at least one embossing portion.

The housing body may include an accommodating space in which the electrical component may be disposed, and the rib may include a plurality of ribs, and the plurality of ribs may be arranged along a circumference of the accommodating space.

The rib may include a contact end facing the contact protrusion, and the contact end of the rib may include a first portion extending in one direction and at least one second portion extending from the first portion in a perpendicular direction.

According to an aspect of the disclosure, there is provided a refrigerator comprising: a main body; a housing body located at a rear of the main body and comprising a side open to accommodate an electrical component, inner and outer surfaces and a rib; and a housing cover disposed to cover the side of the housing body and toward which the rib protrudes and comprising an inner surface and a contact protrusion formed on the inner surface to correspond with and protrude toward the rib, the rib and the contact protrusion being adjacent to the electrical element and initially spaced apart and the contact protrusion being configured to contact the rib in response to a shock being applied to the housing cover.

At least one of the rib and the contact protrusion may comprise a compliant pad element.

According to an aspect of the disclosure, there is provided a refrigerator comprising protrusion may comprise a compliant pad element.

According to an aspect of the disclosure, there is provided a refrigerator comprising: a main body; a housing body located at a rear of the main body and comprising a side open to accommodate electrical components, inner and outer surfaces and a rib disposed among the electrical components; and a housing cover disposed to cover the side of the housing body and toward which the rib protrudes and comprising an inner surface and a contact protrusion formed on the inner surface to respectively correspond with and protrude toward the rib, the rib and the contact protrusion being initially spaced apart and the contact protrusion being configured to contact the rib in response to a shock being applied to the housing cover.

According to an aspect of the disclosure, there is provided a control box including: a housing body having a side that is open to accommodate an electrical component, the housing body including an inner surface facing an inside of the housing body and an outer surface opposite to the inner surface; and a housing cover coupled to the housing body to cover the open side of the housing body, wherein the housing body includes a plurality of ribs protruding toward the housing cover, and the housing cover includes a contact protrusion formed on an inner surface of the housing cover to correspond with the rib, the contact protrusion formed to protrude toward the rib and configured to, in response to a shock being applied to the housing cover, contact the rib.

The rib and the contact protrusion may be located adjacent to electrical components accommodated in the housing body.

The rib and the contact protrusion may be spaced apart from each other.

The housing cover may further include a recess formed on an outer surface of the housing cover to correspond with the contact protrusion.

The rib may be formed at a height such that the rib may be prevented from protruding beyond a rear surface of the refrigerator based on the housing body being coupled to the rear surface of the refrigerator.

The housing cover may include at least one embossing portion formed by an outer surface of the housing cover protruding to form a recess on the inner surface of the housing cover.

### Advantageous Effects

When a shock is applied to a control box of a refrigerator, the shock to be transmitted to electrical components accommodated inside the control box can be reduced.

Noise caused by a rib and a contact protrusion colliding with each other due to vibration of a refrigerator can be prevented.

When a shock is applied to a control box of a refrigerator, the degree to which a housing cover is deformed due to the shock can be reduced by a plurality of embossing portions.

### DESCRIPTION OF DRAWINGS

FIG. 1 is a perspective view illustrating the external appearance of a refrigerator according to an embodiment of the disclosure.

FIG. 2 is an exploded perspective view illustrating a main body of the refrigerator shown in FIG. 1.

FIG. 3 is a rear perspective view illustrating the refrigerator shown in FIG. 1.

FIG. 4 is a perspective view illustrating a control box of the refrigerator shown in FIG. 3.

FIG. 5 is an exploded perspective view illustrating the control box shown in FIG. 4.

FIG. 6 is a front view illustrating a housing cover of the control box of the refrigerator shown in FIG. 3.

FIG. 7 is a front view illustrating a housing body of the control box of the refrigerator shown in FIG. 3.

FIG. 8 is a cross-sectional view taken along line A-A of the control box of the refrigerator shown in FIG. 4.

FIGS. 9A and 9B are enlarged views of the encircled portion of FIG. 8.

FIG. 10 is a cross-sectional view illustrating only the housing body of the control box shown in FIG. 8.

FIGS. 11A and 11B are cross-sectional views illustrating a state in which the housing body shown in FIG. 10 is attached to the main body of the refrigerator.

FIG. 12 is a side view illustrating a state in which the housing cover is attached to the housing body shown in FIGS. 11A and 11B.

FIG. 13 is an exploded perspective view illustrating the control box shown in FIG. 4 in accordance with further embodiments.

### MODES OF THE DISCLOSURE

Embodiments described in the specification and configurations shown in the accompanying drawings are merely exemplary examples of the disclosure, and various modifications may replace the embodiments and the drawings of the disclosure at the time of filing of the present application.

Identical symbols or numbers in the drawings of the disclosure denote components or elements configured to perform substantially identical functions.

Terms used herein are only for the purpose of describing particular embodiments and are not intended to limit to the disclosure. The singular form is intended to include the plural form as well, unless the context clearly indicates otherwise. It should be further understood that the terms “include,” “including,” “have,” and/or “having” specify the presence of stated features, integers, steps, operations, elements, components, and/or groups thereof, but do not preclude the presence or addition of one or more other features, integers, steps, operations, elements, components, and/or groups thereof.

It should be understood that, although the terms “first,” “second,” etc. may be used herein to describe various elements, the elements are not limited by the terms, and the terms are only used to distinguish one element from another. For example, a first element could be termed a second element, and similarly, a second element could be termed a first element without departing from the scope of the disclosure. The term “and/or” includes combinations of one or all of a plurality of associated listed items.

The terms “upper-lower direction,” lower side” and “front-rear direction” used herein are defined based on the drawings, and the shape and position of each element are not limited by the terms.

Hereinafter, embodiments according to the disclosure will be described in detail.

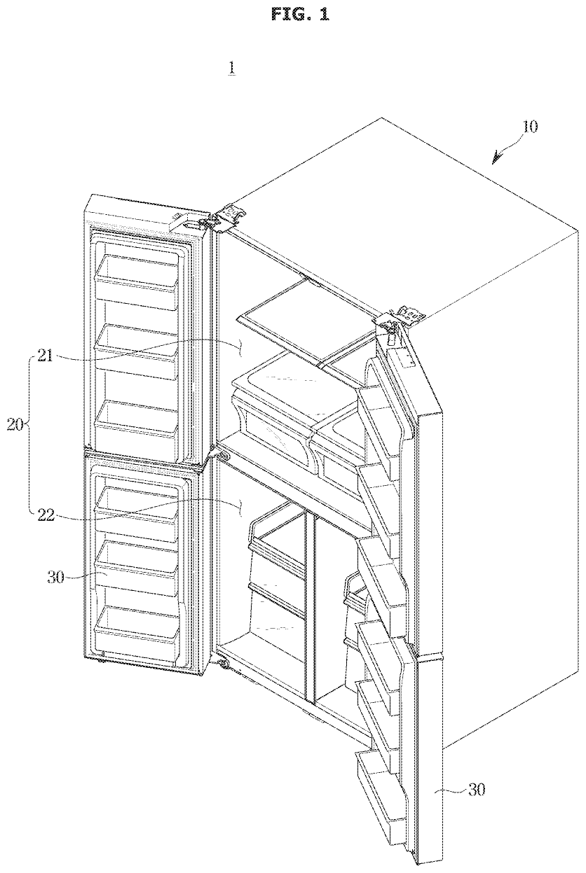

FIG. 1 is a perspective view illustrating the external appearance of a refrigerator according to an embodiment of the disclosure.

Referring to FIG. 1, the refrigerator 1 may include a main body 10, a storage compartment 20 formed inside the main body 10 to store food, and a cold air supply device (not shown) configured to supply the storage compartment 20 with cold air.

In addition, the refrigerator 1 according to an embodiment of the disclosure may include a refrigeration cycle composed of a compressor (not shown), a condenser (not shown), an expander (not shown), and an evaporator (not shown) to generate cold air discharged through a cold air supply device (not shown).

The storage compartment 20 may include an upper storage compartment 21 and a lower storage compartment 22. The upper storage compartment 21 may be a refrigerator compartment, and the lower storage compartment 22 may be a freezer compartment.

Each of the upper storage compartment 21 and the lower storage compartment 22 may be provided with a front that is openable to allow food to be inserted into and withdrawn therethrough. In each case, the open front may be opened and closed by a door 30.

The upper storage compartment 21 and the lower storage compartment may be opened and closed by a pair of rotatable doors 30. That is, the pair of rotatable doors 30 may be rotatably coupled to the main body 10 by a hinge.

The disclosure described below may be applied to various types of refrigerators, such as a French Door Refrigerator (FDR) type refrigerator in which a refrigerator compartment is opened and closed by a pair of doors 30 and a freezer compartment is opened and closed by one door, and a Side By Side (SBS) type refrigerator in which a freezer compartment and a refrigerator compartment are arranged side by side, and a Top Mounted Freezer (TMF) type refrigerator in which a freezer compartment is placed above a refrigerator compartment.

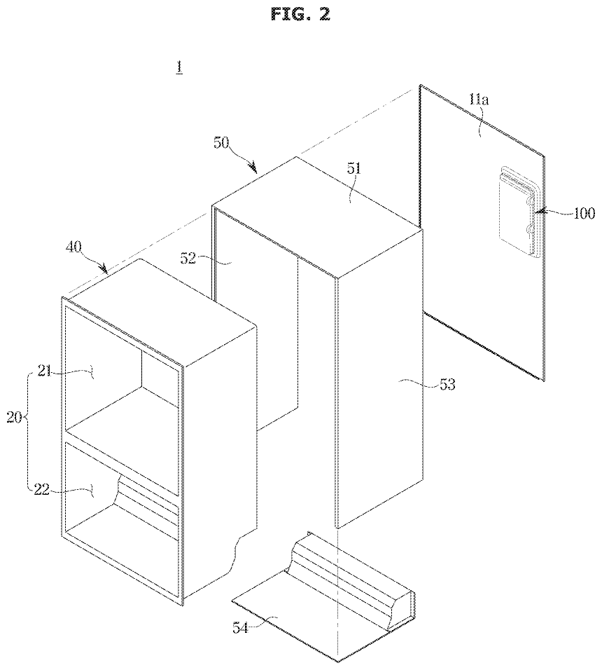

FIG. 2 is an exploded perspective view illustrating a main body of the refrigerator shown in FIG. 1.

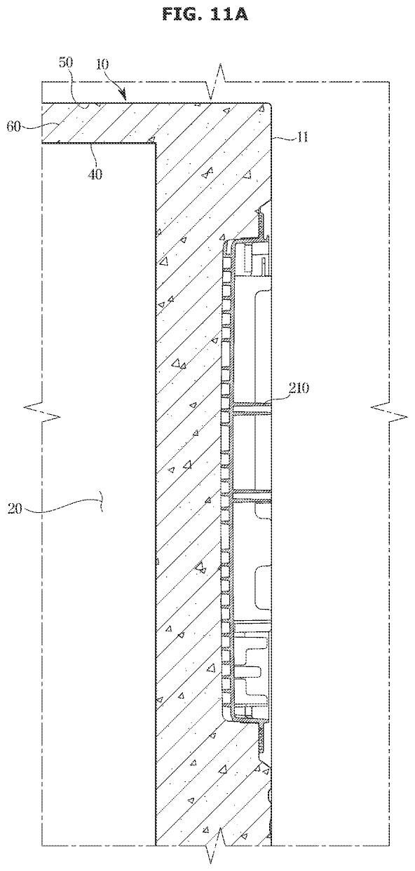

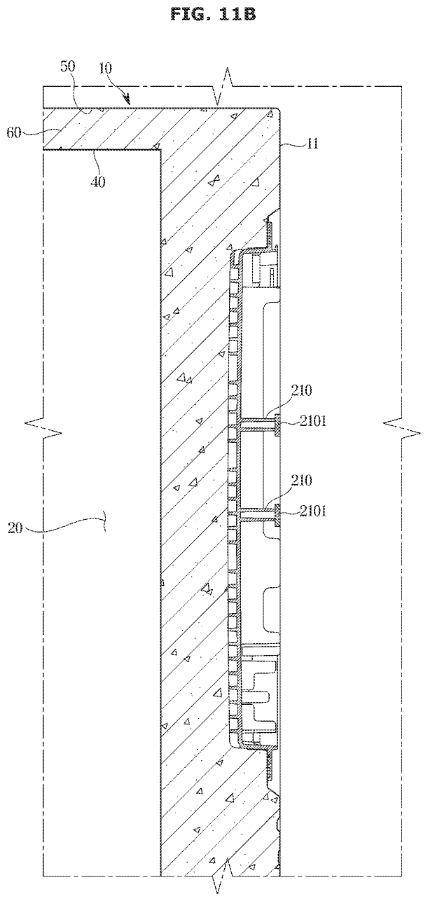

Referring to FIG. 2, the main body 10 of the refrigerator 1 may include an inner case 40 that can be formed in an approximate box shape while having a storage compartment 20 formed therein, an outer case 50 coupled to an outside of the inner case 40 to form the external appearance of the refrigerator 1, and an insulator (60 in FIG. 11) provided between the inner case 40 and the outer case 50 to insulate the outer case 50 and the storage compartment 20.

The inner case 40 may be formed by injection molding a resin material, and the outer case 50 may be formed by press molding a steel plate material. The insulator (60 in FIG. 11) may be formed using foamed urethane, and may be formed by injecting and foaming a foamed urethane liquid into a space between the inner case 40 and the outer case 50 which are assembled with each other.

The outer case 50 may include a top plate 51 that forms the upper exterior of the refrigerator 1, side plates 52 and 53 that form the lateral exterior of the refrigerator 1, a bottom plate 54, and a rear plate 11a that forms the rear exterior of the refrigerator 1. The top plate 51, the side plates 52 and 53, and the rear plate 11a may each be formed to be substantially flat.

As in the embodiment, the top plate 51 and the side plates 52 and 53 may be formed as one single or monolithic part. However, unlike the present embodiment, the side plates 52 and 53 and the bottom plate 54 may be formed as one part, and the top plate 51 may be formed separately.

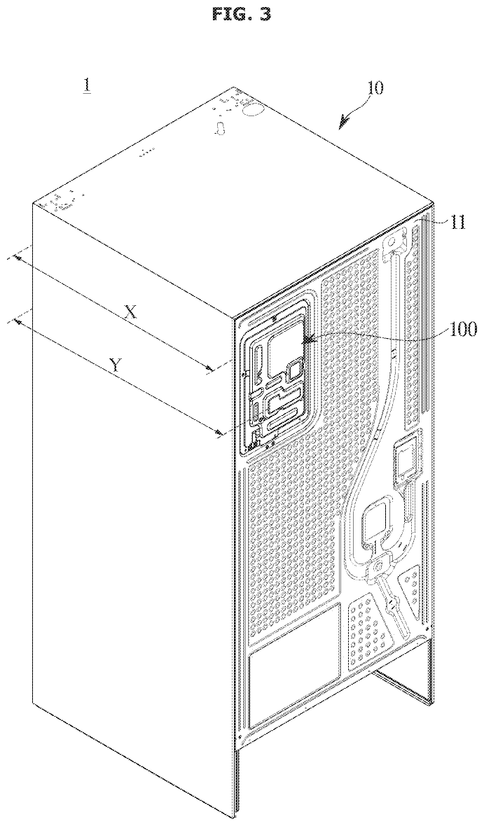

FIG. 3 is a rear perspective view illustrating the refrigerator shown in FIG. 1.

As shown in FIG. 3, the refrigerator 1 may include a control box 100.

The control box 100 may accommodate various electrical components required for operating the refrigerator 1. The electrical components may include a printed circuit board (PCB), a capacitor, and the like. Electrical components may, upon receiving a shock, suffer from a decrease or loss of functionality. The control box 100 may receive a shock applied to the electrical components accommodated therein instead of the electrical components, thereby serving to protect the electrical components.

The control box 100 may be attached to the outer surface of the refrigerator 1. Specifically, the control box 100 may be located on the rear plate 11a that forms a rear surface 11 of the refrigerator 1. Since the control box 100 is located on the outer surface of the refrigerator 1, the control box 100 may easily receive a shock from the outside of the refrigerator 1. Accordingly, the electrical components accommodated in the control box 100 may also be easily subject to a shock.

When a shock is applied to the control box 100, the shock may be transmitted to the electrical components therein. This shock can be transmitted as an inward transmission of a shock as well as a deformation of the control box 100. In any case, the shock can lead to contact between the control box 100 and the electrical components. When such contact occurs between the electrical component and the control box 100, the electrical components may not perform their respective functions properly.

Accordingly, there is a need for a structure that, when a shock is applied to the control box 100, disperses the shock to transmit less shock to the electrical components accommodated inside the control box 100.

Furthermore, there is a need for a technology that allows the control box 100 to be deformed to a small degree in response to a shock being applied to the control box 100. This is because, when severe deformation of the control box 100 occurs, the deformation may cause contact between the control box 100 and the electrical components accommodated therein.

In order to resolve the issues noted above, the control box 100 may be spaced a predetermined distance from the electrical components accommodated therein. By providing the spacing of the predetermined distance, when a shock is applied to the control box 100 and the control box 100 is deformed, a deformed portion of the control box 100 may be prevented from traversing the predetermined distance and contacting the electrical components.

When the predetermined distance between the control box 100 and the electrical components is provided, the control box 100 may protrude to the rear surface 11 of the refrigerator 1 and the refrigerator 1 may be installed at a certain distance from the wall. In particular, home appliances are often installed with a built-in configuration, which limits available space for the refrigerator 1. Therefore, the size of the refrigerator 1 is often designed to fit the space in which the refrigerator 1 is located. However, when a protruding control box 100 is present on the rear surface 11 of the refrigerator 1, the refrigerator 1 needs to be designed to have a size that takes the protruding portion into consideration. As the protruding portion of the control box 100 increases, the depth of the storage compartment 20 of the refrigerator 1 decreases. Therefore, it is appropriate to minimize a portion of the control box 100 protruding to the rear surface 11 of the refrigerator 1 in designing a larger space for the storage compartment 20 of the refrigerator 1.

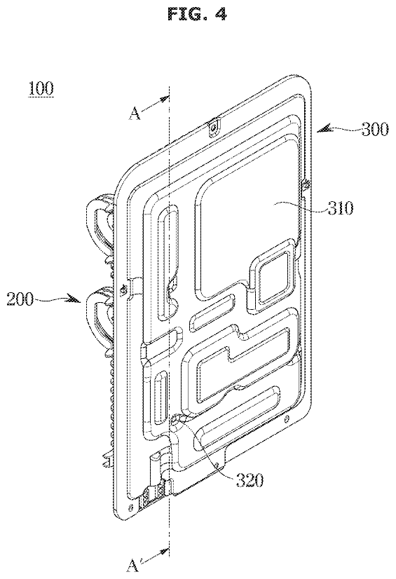

FIG. 4 is a perspective view illustrating a control box of the refrigerator shown in FIG. 3.

As shown in FIG. 4, the control box 100 may include a housing body 200 and a housing cover 300. One side of the housing body 200 may be coupled to the housing cover 300.

The housing cover 300 may include a metal material. In this case, the housing cover 300 may have greater strength than that of the housing cover 300 formed of plastic. When the housing cover 300 has a stronger strength, the housing cover 300 may be deformed in a smaller amount when a shock is applied thereto, and thus the electrical components and the housing cover 300 may have a smaller distance therebetween.

The housing cover 300 may include at least one embossing portion 310 and a contact portion 320.

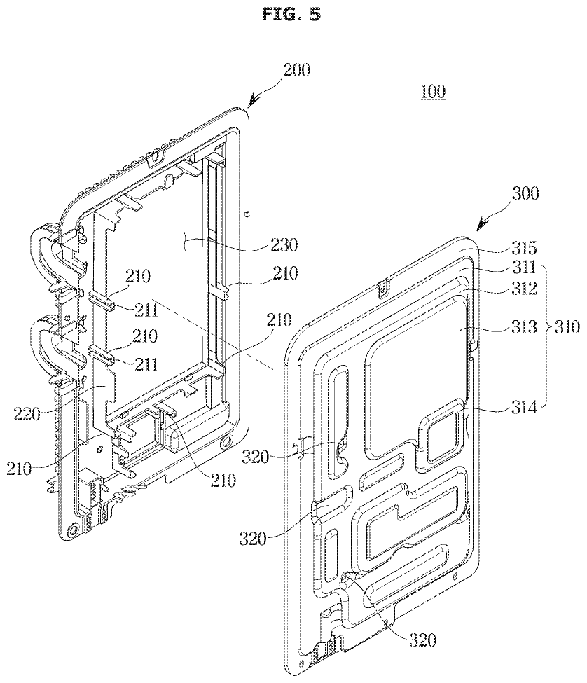

FIG. 5 is an exploded perspective view illustrating the control box shown in FIG. 4.

Referring to FIG. 5, one side of the housing body 200 may be open. Electrical components may be accommodated in the housing body 200 through the open side of the housing body 200. The housing body 200 may prevent direct shock from being applied to the electrical components.

The housing body 200 may be divided into sections to define the locations in which electrical components are to be disposed. The location in which the electrical component is disposed may be referred to as an accommodating space 230. A guide 220 may be formed along the circumference or periphery of the accommodating space 230. When the refrigerator 1 is transported or the control box 100 is moved, the guide 220 may prevent the electrical components from being displaced from the corresponding locations and colliding with each other.

The housing cover 300 may be coupled to the housing body 200 to cover the open side of the housing body 200. Therefore, the electrical components may be protected from external shock by being surrounded by the housing body 200 and the housing cover 300.

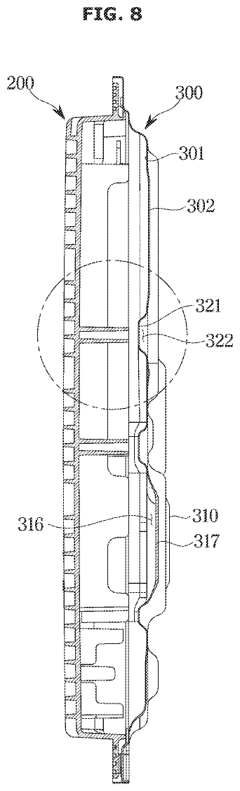

The embossing portion 310 may be formed to protrude in a direction opposite to the direction facing toward the housing body 200. The embossing portion 310 may include an embossing recess (316 in FIG. 8) formed on an inner surface 301 of the housing cover 300 facing the housing body 200, and an embossing protrusion (317 in FIG. 8) formed on an outer surface 302 of the housing cover 300. The embossing protrusion (317 in FIG. 8) may have a flat end tip. Since the end tip of the embossing protrusion (317 in FIG. 8) is formed flat, the extent to which the control box 100 protrudes toward the rear surface 11 of the refrigerator 1 may be reduced as compared to when the end tip is not flat.

Since the housing cover 300 may include a metal material, the forming of a protrusion on the housing cover 300 may be performed through press working. Based on the press working, it may be relatively easy to form embossing with the above described structure.

When the embossing portion 310 is formed on the housing cover 300, the strength of the housing cover 300 may increase. In other words, when a shock is applied to the housing cover 300 on which the embossing portion 310 is formed, the degree of deformation may be less than that when the embossing portion 310 is not present. Therefore, the housing cover 300 including the embossing portion 310 may require a shorter distance to be provided between the housing cover 300 and the electrical components as compared to the distance provided between the housing cover 300 and the electrical components when the housing cover 300 does not include the embossing portion 310. In other words, the housing cover 300 including the embossing portion 310 may protrude less from the rear surface 11 of the main body 10 of the refrigerator 1 even when the housing cover 300 is coupled to the rear surface 11 of the main body 10 of the refrigerator 1. Therefore, the housing cover 300 including the embossing portion 310 may secure a larger space for the storage compartment 20.

The housing cover 300 may include a single embossing portion 310, or may include a plurality of embossing portions 310. When the housing cover 300 includes a plurality of embossing portions 310, the strength of the housing cover 300 may be further increased compared to when the housing cover 300 includes a single embossing portion 310. Therefore, in the case of the housing cover 300 including a plurality of embossing portions 310, the control box 100 may protrude less to the rear surface 11 of the refrigerator 1 as compared to the case of the housing cover 300 including a single embossing portion 310, which in turn secures a larger space for the storage compartment 20.

The plurality of embossing portions 310 may include a first embossing portion 311 forming a step with respect to a base surface 315 of the housing cover 300, a second embossing portion 312 forming a step higher than that of the first embossing portion 311, a third embossing portion 313 forming a step higher than that of the second embossing portion 312, and a fourth embossing portion 314 forming a step higher than that of the third embossing portion 313. In the specification, the embossing portions 310 including first to fourth embossing portions 311 to 314 are taken as an example but the embossing portions 310 may be formed with more various heights.

The first embossing portion 311 may be provided to protrude a predetermined distance from the base surface 315 of the housing cover 300. The first embossing portion 311 may protrude from a part spaced a predetermined distance from the edge of the housing cover 300.

The second embossing portion 312 may protrude from a part spaced a predetermined distance from the edge surface of the first embossing portion 311. Accordingly, the second embossing portion 312 may be provided to further protrude in a direction opposite to the direction toward the housing body 200 based on the protruding surface of the first embossing portion 311.

The third embossing portion 313 may be provided to further protrude in a direction opposite to the direction toward the housing body 200 based on the protruding surface of the second embossing portion 312, and the fourth embossing portion 314 may be provided to further protrude in a direction opposite to the direction toward the housing body 200 based on the protruding surface of the third embossing portion 313.

In summary, the fourth embossing portion 314 further protrudes in a direction away from the housing body 200 than the first embossing portion 311.

The positions of the first to fourth embossing portions 311 to 314 may be determined according to the height and position of the electrical component accommodated inside the housing body 200. When a tall electrical component is accommodated in the housing body 200, the housing cover 300 at a position corresponding to the tall electrical component may include an embossing portion 310 having a greater height. As a result, a predetermined distance may be formed between the tall electrical component and the housing cover 300, thereby effectively protecting the electrical component from a shock.

As alternative embodiments, one or more pairs of the first to fourth embossing portions 311 to 314 need not form steps but may be substantially similar in shape and size or may substantially overlap with one another. For example, the respective corresponding corners of the first, second and third embossing portions 311, 312 and 313 may overlap with one another along a single edge thus forming one large step from the base surface 315.

The housing body 200 may include a rib 210 protruding in a direction toward the housing cover 300. The housing cover 300 may include a contact portion 320 formed at a position corresponding to the rib 210 and contacting the rib 210 when a shock is applied to the housing cover 300. When a shock is applied to the control box 100, the rib 210 and the contact portion 320 may contact each other to disperse the shock applied to the control box 100. Therefore, electrical components may be subject to less shock than they otherwise would be subject to experiencing.

For reference, since the housing cover 300 may be formed of metal, the contact protrusion may be gradually deformed according to contact of the contact protrusion and the rib.

The rib 210 and the contact portion 320 will be described in detail below.

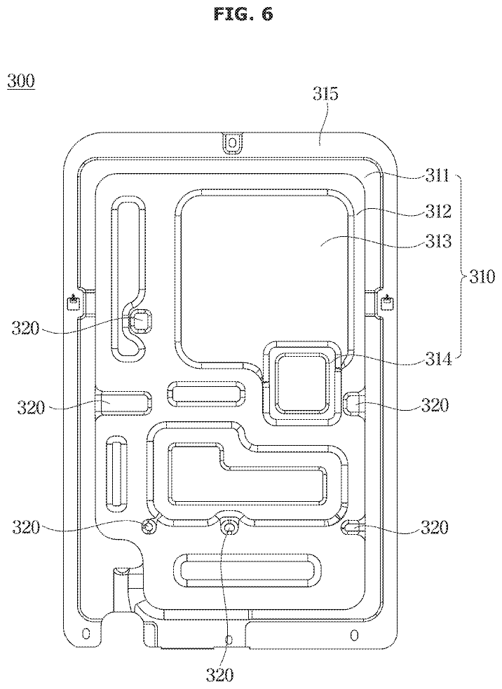

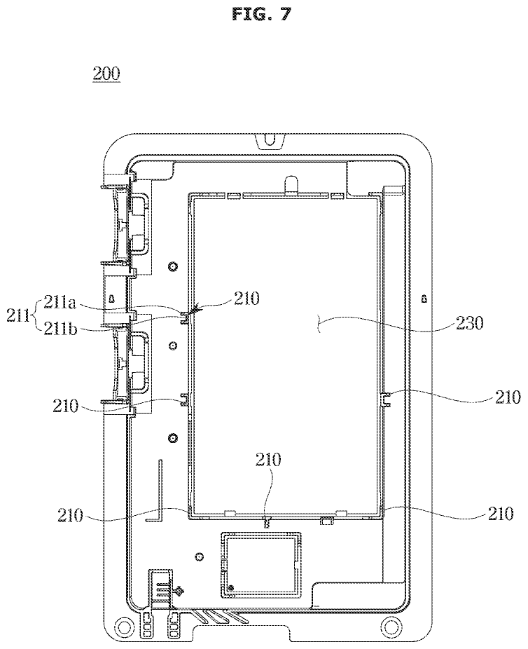

FIG. 6 is a front view illustrating a housing cover of the control box of the refrigerator shown in FIG. 3. FIG. 7 is a front view illustrating a housing body of the control box of the refrigerator shown in FIG. 3.

Referring to FIGS. 6 and 7, the contact portion 320 may be provided at a position corresponding to the rib 210.

The position of the rib 210 may be provided at a location surrounding the electrical component. When a shock is applied to a local part of the control box 100, the shock may first be distributed to the rib 210 and the contact portions 320 at a surrounding of the part to which the shock is applied. Therefore, electrical components at a surrounding of the part to which the shock is applied may be subject to less shock.

In other words, since the electrical component is accommodated in the accommodating space 230, the positions of the ribs 210 may be arranged along the circumference of the accommodating space 230.

The rib 210 may include a contact end 211 facing the contact portion 320. The contact end of the rib 210 may include a first portion 211a extending in one direction and at least one second portion 211b extending from the first portion 211a in a perpendicular direction. For example, the contact end may be L-shaped, T-shaped, I-shaped or U-shaped. Such a shape may provide the rib 210 with a greater strength compared to when the contact end of the rib 210 extends only in a single direction. Therefore, the ribs 210 are less likely to be damaged by a shock.

The rib 210 may be formed in plural, and a plurality of contact portions 320 may be formed at positions corresponding to the plurality of ribs 210.

The contact portion 320 may be provided on the edge of the embossing portion 310. Since the contact portion 320 is similar to the embossing portion 310 in that the contact portion 320 also protrudes from the housing cover 300, the contact portion 320 may increase a size, height or thickness of the housing cover 300.

The contact portion 320 may protrude in a direction opposite to the protruding direction of the embossing portion 310. When the contact portion 320 protrudes in the same direction as the embossing portion 310, it may be difficult to secure a required distance between the electrical component and the control box 100 while maintaining the height of the rib, as shown below. Therefore, in such cases, it may be appropriate to arrange the contact portion 320 and the embossing portion 310 such that the protruding direction of the contact portion 320 is opposite to the protruding direction of the embossing portion 310.

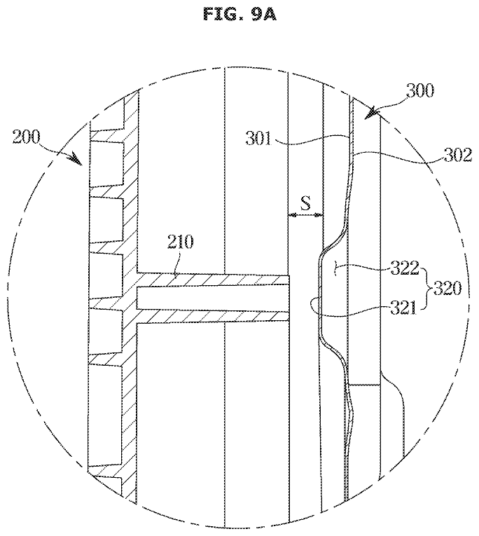

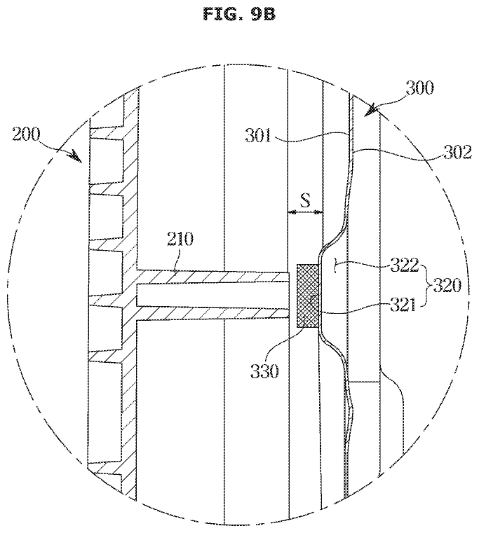

FIG. 8 is a cross-sectional view taken along line A-A of the control box of the refrigerator shown in FIG. 4. FIGS. 9A and 9B are enlarged views of a portion of FIG. 8.

Referring to FIGS. 8 and 9A and 9B, the housing cover 300 may include an inner surface 301 facing the inside of the housing body 200 and an outer surface 302 opposite the inner surface 301.

The contact portion 320 may include a contact protrusion 321 formed on the inner surface 301 of the housing cover 300 to correspond with the rib 210 and to protrude toward the rib 210. As will be described in detail below, the height of the ribs 210 is formed within a certain limitation. Since the housing cover 300 has the embossing portion 310, the housing cove 300 is spaced a predetermined distance from the rib 210. When a shock is applied to the control box 100, the contact portion 320 and the rib 210 need to contact each other to disperse the shock. The rib 210 and the contact portion 320 need to be spaced apart from each other at a certain distance or less, which is close enough to achieve the effect. In this case, when the contact protrusion 321 is not present, the rib 210 and the contact portion 320 may not be spaced apart from each other at the certain distance or less, and thus the contact protrusion 321 is required to achieve the above described effect.

The contact portion 320 may include a recess 322 formed on the outer surface 302 of the housing cover 300 to correspond with the contact protrusion 321. The housing cover 300 may be formed of a metal material, and since in the case of a metal material, the contact protrusion 321 may be formed by a press work, the formation of the recess 322 may be achieved by the press work. In other words, the contact portion 320 may be considered as having a contact protrusion 321 when viewed from the perspective of the inner surface 301 of the housing cover 300 and as having a recess 322 when viewed from the perspective of the outer surface 302 of the housing cover 300.

The contact protrusion 321 may have a flat shape on the end tip, but may also have a round shape. It may be appropriate to forming the end tip of the contact protrusion 321 in a flat shape in adjusting the distance between the contact protrusion 321 and the rib 210. However, when manufacturing the housing cover 300 through a press work, excessive deformation may cause cracks in the product. Therefore, since a flat end tip of the contact protrusion 321 may cause cracks in the product, it may be required to form the end tip of the contact protrusion 321 in a rounded shape within an appropriate range.

The rib 210 and the contact portion 320 may be positioned to be at least initially spaced apart from each other when the housing body 200 and the housing cover 300 are coupled to each other.

Referring to FIG. 9A, the rib 210 and the contact portion 320 may be spaced apart from each other by a certain distance S. The refrigerator 1 often vibrates during operation. In this case, when the rib 210 and the contact portion 320 are excessively close to each other, due to the distance S being small, the rib 210 and the contact portion 320 may make frequent contact and separation due to vibration. In other words, noise may occur. To prevent such an issue, the distance S between the rib 210 and the contact portion 320 may be set to a distance that prevents noise from occurring while allowing the rib 210 and the contact portion 320 to contact each other when a shock is applied to the control box 100.

Referring to FIG. 9B, a compliant pad element 330 can be disposed on the contact portion 320 to face the rib 210 or on the rib 210 to face the contact portion 320. In either case, the compliant pad element 330 can reduce the shock applied by the contact portion 320 to the rib 210 and can further reduce the noise generated by frequent contact and separation of the contact portion 320 and the rib 210 due to vibration. The presence of the compliant pad element 330 can therefore allow for a reduction in the magnitude of the distance S.

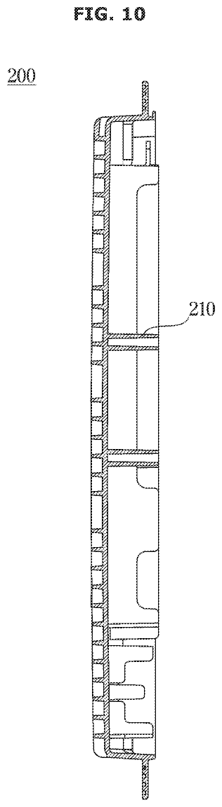

FIG. 10 is a cross-sectional view illustrating only the housing body of the control box shown in FIG. 8.

When the housing body 200 is considered, the height of the rib 210 may be limited to a certain height. This is to prevent the rib 210 from protruding beyond the rear surface 11 of the main body 10 of the refrigerator 1 when the control box is attached to the rear surface 11 of the man body 10 of the refrigerator 1.

FIGS. 11A and 11B are cross-sectional views illustrating a state in which the housing body shown in FIG. 10 is attached to the main body of the refrigerator.

Referring to FIG. 11A, the rib 210 included in the housing body 200 may have a height such that the rib 210 protrudes up to a position corresponding to the rear surface 11 of the refrigerator 1 when the housing body 200 is coupled to the rear surface 11 of the refrigerator 1.

As described above, the main body 10 of the refrigerator 1 may include the inner case 40 having the storage compartment 20 formed therein, the outer case 50 coupled to the outside of the inner case 40 to form the external appearance of the refrigerator 1, and the insulator provided between the inner case 40 and the outer case 50 to insulate the outer case 50 and the storage compartment 20.

The inner case 40 may be formed by injection molding a resin material, and the outer case 50 may be formed by press molding a steel plate material. The insulator may be formed using foamed urethane, and may be formed by assembling the inner case 40 and the outer case 50, and then injecting and foaming a foamed urethane liquid into a space between the inner case 40 and the outer case 50.

When injecting and foaming a foamed urethane liquid between the inner case 40 and the outer case 50, the refrigerator 1 may be introduced into a machine for injecting and foaming a foamed urethane liquid while the rear surface 11 faces down. In this case, a plate is placed under the rear surface 11 of the refrigerator 1 to withstand the pressure generated on the rear surface 11 of the refrigerator 1 when a foamed urethane liquid is injected. In this case, the rear surface 11 of the refrigerator 1 needs to be subject to a uniform pressure. Otherwise, the shapes of the inner case 40 and the outer case 50 of the refrigerator 1 may be distorted.

When the rib 210 protrudes beyond the rear surface 11 of the main body 10, the plate supporting the rear surface 11 of the main body 10 of the refrigerator 1 during a process of injecting a formed urethane liquid may have a shape for accommodating the rib 210 rather than a flat plate shape. Such a shape may enable the process of injecting a foamed urethane liquid while maintaining the refrigerator 1 placed on the plate in a horizontal state. In addition, such a shape may allow a uniform pressure of the foamed urethane liquid to be applied to the rear surface 11 of the refrigerator 1.

However, the position at which the housing cover 300 is coupled to the rear surface 11 of the main body 10 of the refrigerator 1 may vary for different models of the refrigerator 1. Therefore, when the rib 210 protrudes beyond the rear surface 11 of the main body 10 of the refrigerator 1, the plate supporting the rear surface 11 of the main body 10 of the refrigerator 1 during a process of injecting a foamed urethane liquid needs to have a shape that accommodates the rib 210 at a different position depending on the model of the refrigerator 1.

However, when the rib 210 does not protrude beyond the rear surface 11 of the main body 10, the plate supporting the rear surface 11 of the main body 10 during the process of injecting the foamed urethane liquid may be implemented using a plate with a uniform, flat shape even for different models of the refrigerator 1. In other words, when the rib 210 does not protrude beyond the rear surface 11 of the main body 10, the efficiency of the process increases.

Referring to FIG. 11B, the rib 210 included in the housing body 200 may include a compliant pad element 2101 similar to the compliant pad element 330 of FIG. 9B. In such cases, the rib 210 and the compliant pad element 2101 may have a total height such that the rib 210 with the compliant pad element 2101 protrudes up to a position corresponding to the rear surface 11 of the refrigerator 1 when the housing body 200 is coupled to the rear surface 11 of the refrigerator 1.

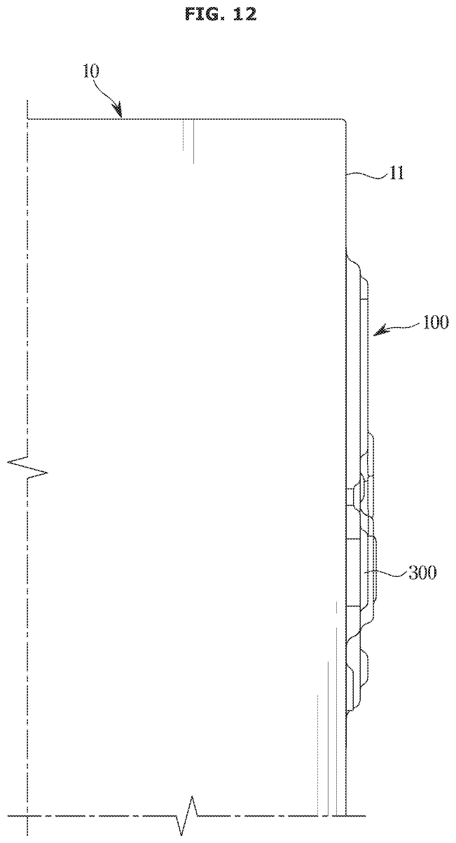

FIG. 12 is a side view illustrating a state in which the housing cover is attached to the housing body shown in FIGS. 11A and 11B.

Referring to FIG. 12, after the application of the foamed urethane liquid to the refrigerator 1 is completed, the housing cover 300 is coupled to the housing body (200 in FIG. 11).

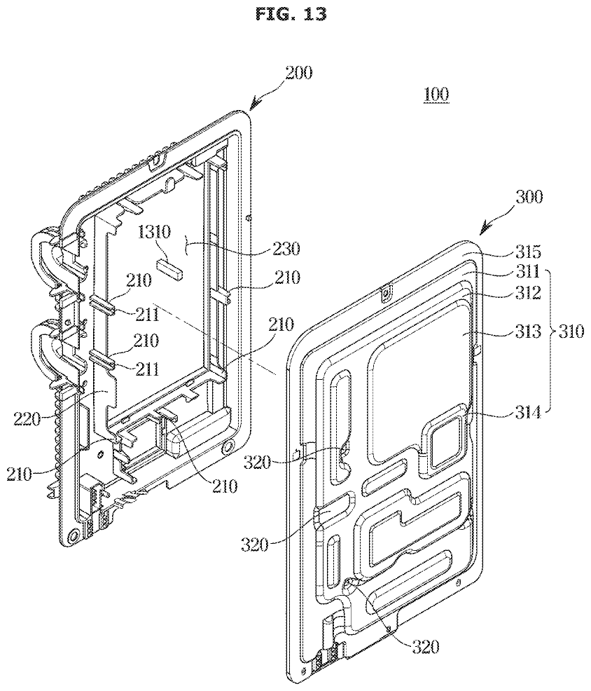

Referring to FIG. 13, in addition to the plural ribs 210 and the plural contact portions 320, the housing body 200 may further include one or more additional ribs 1310 protruding from the accommodating space 230 (i.e., among the electrical component(s) and in a direction oriented toward the housing cover 300. When a shock is applied to the control box 100, each of the ribs 210 and the one or more additional RIBS 1310 and each corresponding one of the contact portions 320 may contact each other to disperse the shock applied to the control box 100. Therefore, the electrical component(s) may be subject to less shock than they otherwise would be subject to experiencing.

Since the housing cover 300 protrude to the rear surface 11 of the main body 10 of the refrigerator 1 in a coupled state, the degree of protrusion toward the rear surface 11 of the main body 10 of the refrigerator 1 needs to be reduced in view of the effects described above.

While the disclosure has been shown and described with reference to various embodiments thereof, it will be understood by those skilled in the art that various changes in form and details may be made therein without departing from the spirit and scope of the disclosure as defined by the appended claims and their equivalents.

1. A refrigerator comprising:
a main body;
a storage compartment arranged inside the main body;
a housing body located at a rear of the main body and having a side that is open to accommodate an electrical component, the housing body including an inner surface facing an inside of the housing body and an outer surface opposite to the inner surface; and
a housing cover coupled to the housing body to cover the open side of the housing body,
wherein the housing body includes a rib protruding toward the housing cover, and
the housing cover includes a contact protrusion formed on an inner surface of the housing cover to correspond with the rib, the contact protrusion formed to protrude toward the rib and configured to, in response to a shock being applied to the housing cover, contact the rib.

2. The refrigerator of claim 1, wherein the rib and the contact protrusion are located adjacent to the electrical component.

3. The refrigerator of claim 1, wherein the rib and the contact protrusion are spaced apart from each other.

4. The refrigerator of claim 1, wherein the housing cover further includes a recess formed on an outer surface thereof to correspond with the contact protrusion.

5. The refrigerator of claim 1, wherein the contact protrusion includes a rounded shape at an end that faces toward the housing body.

6. The refrigerator of claim 1, wherein the contact protrusion comprises a compliant pad element facing the rib.

7. The refrigerator of claim 1, wherein the rib is formed at a height such that the rib is prevented from protruding beyond a rear surface of the refrigerator when the housing body is coupled to the rear surface of the refrigerator.

8. The refrigerator of claim 1, wherein the rib comprises a compliant pad element and the rib and the compliant pad element are formed at a total height such that the rib and the compliant pad element are prevented from protruding beyond a rear surface of the refrigerator when the housing body is coupled to the rear surface.

9. The refrigerator of claim 1, wherein the housing cover includes a metal material, and the contact protrusion is deformable according to contact between the rib and the contact protrusion.

10. The refrigerator of claim 1, wherein the housing cover includes at least one embossing portion formed by an outer surface of the housing cover protruding to form a recess on the inner surface of the housing cover.

11. The refrigerator of claim 10, wherein the at least one embossing portion includes a first embossing portion formed at a position corresponding to the electrical component and a second embossing portion protruding from an outer surface of the first embossing portion.

12. The refrigerator of claim 11, wherein the first and second embossing portions form multiple steps.

13. The refrigerator of claim 11, wherein the first and second embossing portions form a single step.

14. The refrigerator of claim 10, wherein the contact protrusion is formed on an edge of the at least one embossing portion.

15. The refrigerator of claim 10, wherein the contact protrusion protrudes in a direction opposite to a protruding direction of the at least one embossing portion.

16. The refrigerator of claim 1, wherein the housing body includes an accommodating space in which the electrical component is disposed, and
the rib includes a plurality of ribs, and the plurality of ribs are arranged along a circumference of the accommodating space.

17. The refrigerator of claim 1, wherein the rib includes a contact end facing the contact protrusion, and
the contact end of the rib includes a first portion extending in one direction and at least one second portion extending from the first portion in a perpendicular direction.

18. A refrigerator comprising:
a main body;
a housing body located at a rear of the main body and comprising a side open to accommodate an electrical component, inner and outer surfaces and a rib; and
a housing cover disposed to cover the side of the housing body and toward which the rib protrudes and comprising an inner surface and a contact protrusion formed on the inner surface to correspond with and protrude toward the rib,
the rib and the contact protrusion being adjacent to the electrical element and initially spaced apart and the contact protrusion being configured to contact the rib in response to a shock being applied to the housing cover.

19. The refrigerator of claim 18, wherein at least one of the rib and the contact protrusion comprises a compliant pad element.

20. A refrigerator comprising:
a main body;
a housing body located at a rear of the main body and comprising a side open to accommodate electrical components, inner and outer surfaces and a rib disposed among the electrical components; and
a housing cover disposed to cover the side of the housing body and toward which the rib protrudes and comprising an inner surface and a contact protrusion formed on the inner surface to respectively correspond with and protrude toward the rib,
the rib and the contact protrusion being initially spaced apart and the contact protrusion being configured to contact the rib in response to a shock being applied to the housing cover.
